(19) United States
(12) Patent Application Publication
(10) Pub. No.: US 2006/0113590 A1
(43) Pub. Date: Jun. 1, 2006

(54) Method of forming a recess structure, recessed channel type transistor and method of manufacturing the recessed channel type transistor

(75) Inventors: Ji-Hae Kim, Gyeonggi-do (KR); Ji-Young Kim, Gyeonggi-do (KR); Jong-Chul Park, Gyeonggi-do (KR); Yong-Sun Ko, Gyeonggi-do (KR); Sang-Sup Jeong, Gyeonggi-do (KR)

Correspondence Address: MYERS BIGEL SIBLEY & SAJOVEC, PO BOX 37428, RALEIGH, NC, 27627, US

(73) Assignee: Samsung Electronics Co., Ltd.

(21) Appl. No.: 11/285,558

(22) Filed: Nov. 22, 2005

(30) Foreign Application Priority Data
Nov. 26, 2004 (KR) 10-2004-0098014
Jul. 20, 2005 (KR) 10-2005-0065777

(51) Int. Cl. H01L 29/94

(52) U.S. Cl. 257/330

(57) ABSTRACT

An isolation layer having a first depth is formed from an upper face of a substrate. Source/drain regions including junctions are formed in the substrate. Each of the junctions has a second depth substantially smaller than the first depth. A first recess is formed in the substrate by a first etching process. A protection layer pattern is formed on a sidewall of the first recess. A second recess is formed beneath the first recess. The second recess has a width substantially larger than that of the first recess. The second recess is formed by a second etching process using an etching gas containing an SF₆ gas, a Cl₂ gas and an O₂ gas. A gate insulation layer is formed on surfaces of the first and the second recesses. The second recess having an enlarged shape may reduce a width of the junction between the gate electrode and the isolation layer so that a leakage current generated through the junction may decrease.

### CROSS-REFERENCE TO RELATED APPLICATIONS

This application claims priority under 35 USC § 119 of Korean Patent Application No. 2004-98014 filed on Nov. 26, 2004, and Korean Patent Application No. 2005-65777 filed on Jul. 20, 2005, the contents of which are herein incorporated by references in their entireties.

### FIELD OF THE INVENTION

Embodiments of the present invention relate to a method of forming a recess structure, a recessed channel type transistor having the recess structure, and a method of manufacturing a recessed channel transistor. More particularly, embodiments of the present invention relate to a method of forming a recess structure having an improved construction, a recessed channel type transistor including the recess structure to have enhanced electrical characteristics, and a method of manufacturing the recessed channel type transistor including the recess structure.

### BACKGROUND OF THE INVENTION

As semiconductor devices become highly integrated, patterns formed on an active region of a transistor, for example, a metal-oxide semiconductor (MOS) transistor, may have greatly reduced widths and intervals so that a channel length of the transistor may be considerably decreased. When the channel length of a transistor is less than an effective channel length of the transistor required for proper operation, a short channel effect may occur in the transistor which may deteriorate electrical characteristics of the transistor. Thus, the transistor should have a sufficient channel length to ensure a proper operation thereof even though elements of the transistor may have greatly reduced dimensions.

To increase an effective channel length without the short channel effect, a recessed channel type transistor has been developed. For example, U.S. Pat. No. 6,150,670 (issued to Faltermeier et al.) discloses a vertical type transistor that has a gate electrode buried in a recess formed at an upper portion of a substrate. Additionally, U.S. Pat. No. 6,476,444 (issued to Min et al.) provides a recessed gate electrode having an enlarged lower portion to increase a channel length thereof.

FIGS. 1A and 1B are cross-sectional views illustrating a conventional method of forming a recess for a gate electrode of a recessed channel type transistor. FIG. 1A illustrates the recess formed in an active region of a substrate along a first direction, and FIG. 1B illustrates the recess formed in the active region of the substrate along a second direction perpendicular to the first direction.

Referring to FIG. 1A, gate trenches 14 for forming a recessed channel type transistor are formed in an active region of a substrate 10 having an isolation layer 12. In formation of the gate trenches 14, the silicon fences 16 remain between gate trenches 14 and the isolation layer 12 as shown FIG. 1B.

A wet etching process is performed to enlarge the gate trenches 14 and to remove the silicon fences 16. However, critical dimensions (CD) of the gate trenches 14 may become too large, so that these gate trenches 14 may not be advantageously employed for a recessed channel type transistor having minute design rules.

### SUMMARY OF THE INVENTION

Embodiments of the present invention provide a method of forming a recess structure having an enlarged lower portion.

Embodiments of the present invention provide a recessed channel type transistor including a gate electrode partially buried in a recess structure to improve electrical characteristics.

Embodiments of the present invention provide a method of manufacturing a recessed channel type transistor having a gate electrode partially buried in a recess structure.

According to embodiments of the present invention, there is provided a method of forming a recess structure. A first recess is formed in a substrate by a first etching process. A protection layer pattern is formed on a sidewall of the first recess. A second recess is formed beneath the first recess by a second etching process using an etching gas containing an SF₆ gas, a Cl₂ gas and an O₂ gas. The second recess has a width substantially larger than that of the first recess.

According to embodiments of the present invention, the first etching process may comprise an isotropic etching process, and the second etching process may comprise an anisotropic etching process.

According to embodiments of the present invention, a flow rate ratio among the SF₆ gas, the Cl₂ gas and the O₂ gas may be in a range of about 1.0:6.0:0.2 to about 1.0:6.0:0.3.

According to embodiments of the present invention, the second etching process may be performed at a pressure of about 15 to about 25 mTorr and for about 5 to about 15 seconds by applying a power of about 400 to about 600 W.

According to embodiments of the present invention, the second recess may substantially have a cross-section with an elliptical shape, a track shape or a circular shape.

According to embodiments of the present invention, a ratio between the width of the second recess and a depth of the second recess may be in a range of about 1.0:1.0 to about 1.0:1.5.

According to embodiments of the present invention, the protection layer pattern may be formed using a material that has an etching selectivity to the substrate.

According to embodiments of the present invention, the protection layer pattern may be formed using silicon oxide, silicon nitride or titanium nitride.

According to embodiments of the present invention, there is provided a recessed channel type transistor including a gate insulation layer formed on a surface of a recess structure, and a gate electrode formed on the gate insulation layer and partially buried in the recess structure. The recess structure is formed in a substrate. The recess structure includes a first recess formed from an upper face of the substrate and a second recess formed beneath the first recess. The second recess has a width substantially larger than that of the first recess.

According to embodiments of the present invention, the first recess may have an inclined sidewall, and the second recess may have a rounded sidewall and a rounded bottom.

According to embodiments of the present invention, the gate electrode may include a lower portion partially buried in the recess structure, and an upper portion protruded from the upper face of the substrate.

According to embodiments of the present invention, the gate electrode may include a first conductive pattern partially buried in the recess structure, and a second conductive pattern formed on the first conductive pattern.

According to embodiments of the present invention, there is provided a recessed channel type transistor including an isolation layer, source/drain regions, a gate insulation layer, and a gate electrode. The isolation layer has a first depth from an upper face of a substrate. The source/drain regions are formed in the substrate. The source/drain regions include junctions having second depths substantially smaller than the first depth. The gate insulation layer is formed on a surface of a recess structure formed in the substrate adjacent to the source/drain regions. The recess structure includes a first recess formed between the source/drain regions and a second recess formed beneath the first recess. The second recess has a maximum width adjacent to the second depth. The gate electrode is formed on the gate insulation layer to fill up the recess structure.

According to embodiments of the present invention, the junctions may be positioned between the isolation layer and the second recess.

According to embodiments of the present invention, the gate electrode may include a lower portion having an enlarged cross-section of an elliptical shape, a track shape or a circular shape.

According to embodiments of the present invention, there is provided a method of manufacturing a recessed channel type transistor. An isolation layer having a first depth is formed from an upper face of a substrate. Source/drain regions including junctions are formed in an active region of the substrate. Each of the source/drain regions has a second depth substantially smaller than the first depth. A first recess is formed in the source/drain regions by a first etching process. A protection layer pattern is formed on a sidewall of the first recess. A second recess is formed beneath the first recess by a second etching process using an etching gas containing an SF₆ gas, a Cl₂ gas and an O₂ gas. The second recess has a width substantially larger than that of the first recess. A gate insulation layer is formed on surfaces of the first and the second recesses. A gate electrode is formed on the gate insulation layer to fill up the first recess and the second recess.

According to embodiments of the present invention, the isolation layer may be inclined by an angle of about 80 to about 90° relative to a surface of the substrate.

According to embodiments of the present invention, the second recess may have a maximum width adjacent to the junction.

According to embodiments of the present invention, before forming the source/drain regions, a first impurity region may be formed in the substrate, and then a second impurity region may be formed in the first impurity region. The first impurity region may have a third depth substantially greater than the first depth. The second impurity region may have a fourth depth substantially greater than the second depth and substantially smaller than the third depth. The source/drain regions may be formed in the second impurity region.

According to embodiments of the present invention, the first and the second impurity regions may each have a first conductive type, and the source/drain regions may each have a second conductive type, different from the first conductive type.

According to embodiments of the present invention, the first impurity region may be formed by implanting elements in Group III with an energy of about 90 to about 110 keV to have a first impurity concentration of about 4×10¹¹ to about 4×10¹³ atoms/cm². The second impurity region may be formed by implanting elements in Group III with an energy of about 40 to about 60 keV to have a second impurity concentration of about 6×10¹¹ to about 6×10¹³ atoms/cm². The source/drain region may be formed by implanting elements in Group V with energies of about 5 to about 15 keV to have third impurity concentrations of about 1×10¹² to about 1×10¹⁴ atoms/cm².

According to embodiments of the present invention, the protection layer pattern may be removed before forming the gate insulation layer.

According to embodiments of the present invention, the first recess may have a width of about 500 to about 900 Å. The protection layer pattern may have a thickness of about 40 to about 100 Å. The second recess may have a width of about 500 to about 1,350 Å.

According to embodiments of the present invention, there is provided a method of manufacturing a recessed channel type transistor. An isolation layer having a first depth is formed from an upper face of a substrate. A first recess is formed in the substrate by a first etching process. A protection layer pattern is formed on a sidewall of the first recess. A second recess is formed beneath the first recess by a second etching process using an etching gas containing an SF₆ gas, a Cl₂ gas and an O₂ gas. The second recess has a width substantially larger than that of the first recess. A gate insulation layer is formed on surfaces of the first and the second recesses. A gate electrode is formed on the gate insulation layer. Source/drain regions having junctions are formed adjacent to the gate electrode. Each of the junctions has a second depth substantially smaller than the first depth.

According to embodiments of the present invention, a recessed channel type transistor includes a gate electrode that has a lower portion partially buried in a substrate and enlarged with an elliptical shape, a track shape or a circular shape in accordance with a recess structure. Additionally, the recessed channel type transistor includes source/drain regions formed from an upper face of the substrate to a portion of the substrate where the gate electrode has a maximum width. Thus, a junction of the transistor may have a reduced width to thereby decrease junction leakage current from the junction. Further, the transistor may include a channel region having a greatly increased length in accordance with the enlarged gate electrode because the channel region is formed along the gate electrode. As a result, the recessed channel type transistor may have enhanced electrical characteristics and improved reliability.

### BRIEF DESCRIPTION OF THE DRAWINGS

The above and other features and advantages of the present invention will become more apparent by describing embodiments thereof with reference to the accompanying drawings, in which:

FIGS. 1A and 1B are cross-sectional views illustrating a conventional method of forming a recess for a gate electrode of a recessed channel type transistor;

FIGS. 2A to 2C are cross-sectional views illustrating a method of forming a recess structure in accordance with an embodiment of the present invention;

FIGS. 3A and 3B are cross-sectional views illustrating a recessed channel type transistor in accordance with an embodiment of the present invention;

FIG. 4 is a cross-sectional view illustrating a recessed channel type transistor in accordance with an embodiment of the present invention;

FIGS. 5A to 5G are cross-sectional views illustrating a method of manufacturing a recessed channel type transistor in accordance with an embodiment of the present invention; and

FIGS. 6A and 6B are cross-sectional views illustrating a method of manufacturing a recessed channel type transistor in accordance with an embodiment of the present invention.

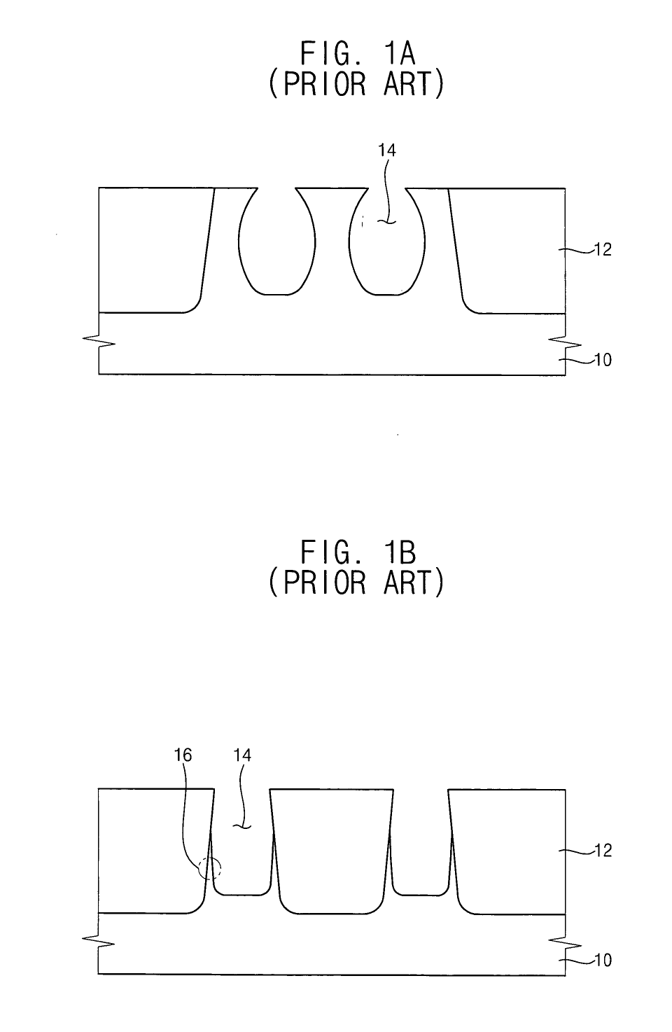

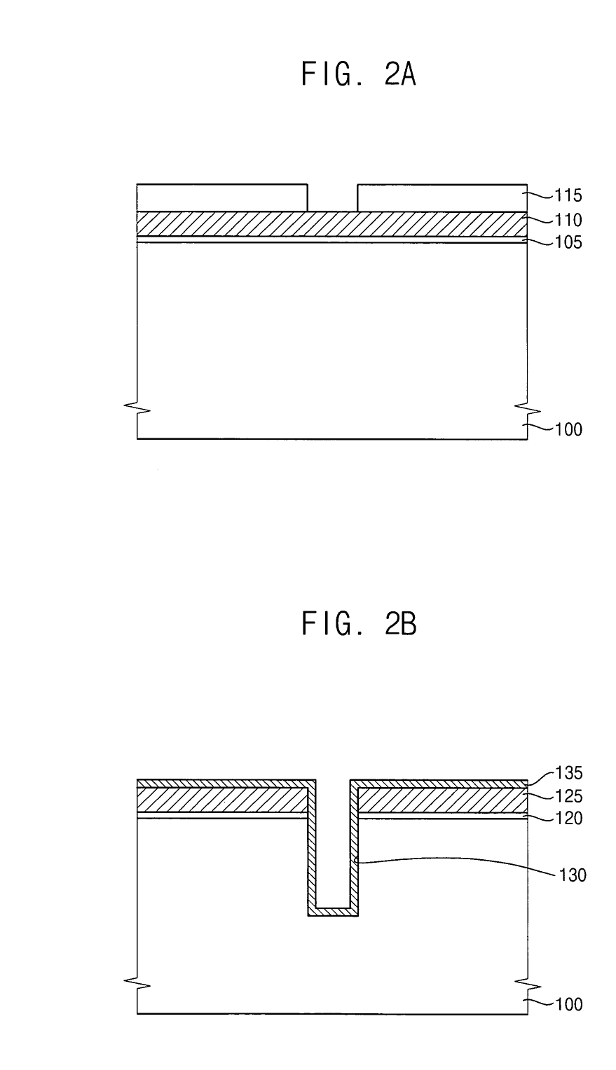

### DESCRIPTION OF THE EMBODIMENTS

The present invention is described more fully hereinafter with reference to the accompanying drawings, in which embodiments of the present invention are shown. The present invention may, however, be embodied in many different forms and should not be construed as limited to the embodiments set forth herein. Rather, these embodiments are provided so that this disclosure will be thorough and complete, and will fully convey the scope of the present invention to those skilled in the art. In the drawings, the sizes and relative sizes of layers and regions may be exaggerated for clarity.

It will be understood that when an element or layer is referred to as being “on”, “connected to” or “coupled to” another element or layer, it can be directly on, connected or coupled to the other element or layer or intervening elements or layers may be present. In contrast, when an element is referred to as being “directly on,” “directly connected to” or “directly coupled to” another element or layer, there are no intervening elements or layers present. Like numbers refer to like elements throughout. As used herein, the term “and/or” includes any and all combinations of one or more of the associated listed items.

It will be understood that, although the terms first, second, third etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of the present invention.

Spatially relative terms, such as “beneath”, “below”, “lower”, “above”, “upper” and the like, may be used herein for ease of description to describe one element or feature's relationship to another element(s) or feature(s) as illustrated in the drawings. It will be understood that the spatially relative terms are intended to encompass different orientations of the device in use or operation in addition to the orientation depicted in the drawings. For example, if the device in the drawings is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Embodiments of the invention are described herein with reference to cross-section illustrations that are schematic illustrations of idealized embodiments (and intermediate structures) of the invention. As such, variations from the shapes of the illustrations as a result, for example, of manufacturing techniques and/or tolerances, are to be expected. Thus, embodiments of the invention should not be construed as limited to the particular shapes of regions illustrated herein but are to include deviations in shapes that result, for example, from manufacturing. For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the drawings are schematic in nature and their shapes are not intended to illustrate the actual shape of a region of a device and are not intended to limit the scope of the invention.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Method of Forming a Recess Structure

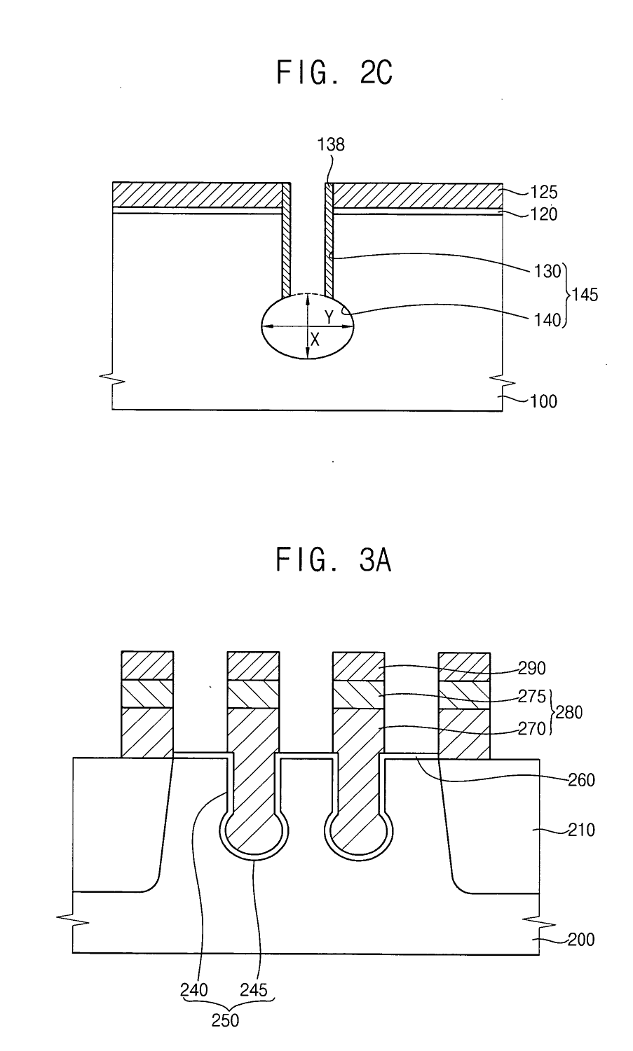

FIGS. 2A to 2C are cross-sectional views illustrating a method of forming a recess structure in accordance with an embodiment of the present invention.

Referring to FIG. 2A, a pad oxide layer 105 is formed on a substrate 100. The substrate 100 may include a silicon wafer, a silicon-on-insulator (SOI) substrate or a single crystalline metal-oxide substrate. The pad oxide layer 105 may be formed using an oxide such as silicon oxide by a thermal oxidation process, a chemical vapor deposition (CVD) process, a plasma-enhanced chemical vapor deposition (PECVD) process or a high-density plasma-chemical vapor deposition (HDP-CVD) process. The pad oxide layer 105 may reduce a stress generated between the substrate 100 and a hard mask layer 110 successively formed.

The hard mask layer 110 is formed on the pad oxide layer 105. The hard mask layer 110 may be formed using a material that has an etching selectivity with respect to the substrate 100 and the pad oxide layer 105. For example, the hard mask layer 110 is formed using a nitride such as silicon nitride or an oxynitride such as silicon oxynitride. The hard mask layer 110 may be formed by a CVD process, a PECVD process or an atomic layer deposition (ALD) process.

After a photoresist film (not shown) is formed on the hard mask layer 110, the photoresist film is exposed and developed to thereby form a photoresist pattern 115 on the hard mask layer 110.

Referring to FIG. 2B, the hard mask layer 110 is partially etched using the photoresist pattern 115 as an etching mask, thereby forming a hard mask pattern 125 on the pad oxide layer 105. The hard mask pattern 125 may define a region of the substrate 100 where a first recess 130 is formed.

After the photoresist pattern 115 is removed from the hard mask pattern 125 by an ashing process and/or a stripping process, the pad oxide layer 105 and the substrate 100 are partially etched by a first etching process using the hard mask pattern 125 as an etching mask. Hence, the first recess 130 is formed at an upper portion of the substrate 100. After the first etching process, the first recess 130 is formed at the upper portion of the substrate 100, and a pad oxide layer pattern 120 is formed between the substrate 100 and the hard mask layer pattern 125. The first etching process may include a reactive ion etch (RIE) process or a chemical dry etch (CDE) process. Additionally, the first etching process may include an anisotropic etching process. As a result, the first recess 130 may be vertically formed at the upper portion of the substrate 100.

According to embodiments of the present invention, the photoresist pattern 115 may be removed by the ashing process and/or the stripping process after the first recess 130 is formed at the upper portion of the substrate along a vertical direction.

According to embodiments of the present invention, the photoresist pattern 115 may be removed in the first etching process without any additional process. Particularly, the photoresist pattern 115 may be completely consumed in the first etching process for forming the first recess 130.

Still referring to FIG. 2B, a protection layer 135 is formed on a sidewall of the first recess 130, the hard mask pattern 125 and on a portion of the substrate 100 (i.e., a bottom of the first recess 130) exposed through the first recess 130. The protection layer 135 may be formed using a material that has an etching selectivity relative to the substrate 100. For example, the protection layer 135 may be formed using an oxide such as silicon oxide or a nitride like silicon nitride or titanium nitride. The protection layer 135 may be formed by a thermal oxidation process, a CVD process, a PECVD process, an HDP-CVD process or an ALD process.

Referring to FIG. 2C, the protection layer 135 is partially etched to form a protection layer pattern 138 on the sidewall of the first recess 130. In particular, portions of the protection layer 135 positioned on the hard mask pattern 125 and the bottom of the first recess 130 are removed to thereby form the protection layer pattern 138 on the sidewall of the first recess 130 only. The protection layer pattern 138 may be formed by an etch back process. Further, the protection layer pattern 138 may be formed by a dry etching process.

Using the protection layer pattern 138 as an etching mask, the exposed portion of the substrate 100 (the bottom of the first recess 130) is etched by a second etching process. Thus, a recess structure 145 having the first recess 130 and a second recess 140 is formed at the upper portion of the substrate 100. The second recess 140 is positioned beneath the first recess 130. The second recess 140 has a width substantially wider than that of the first recess 130. For example, the second recess 140 has a cross-section with an elliptical shape or a track shape. The term “track shape” is defined herein to mean any generally circular or oval shape that may or may not include one or more generally linear sections.

In an example embodiment of the present invention, the second etching process may include an isotropic etching process. For example, the second recess 140 may be formed using an etching gas that contains an SF₆ gas, a Cl₂ gas and an O₂ gas. Particularly, the etching gas may include the SF₆ gas, the Cl₂ gas and the O₂ gas by a flow rate ratio in a range of from about 1.0:6.0:0.2 to about 1.0:6.0:0.3. Additionally, the second etching process may be performed at a pressure of about 15 to about 25 mTorr for about 5 to about 15 seconds by applying a power of about 400 to about 600 W. For example, the second etching process for forming the second recess 140 may be performed at a pressure of about 20 mTorr for about 10 seconds by applying a power of about 600 W while using an etching gas that includes the SF₆ gas, the Cl₂ gas and the O₂ gas by using a flow rate ratio of about 1.0:6.0:0.25.

After the second etching process, the second recess 140 may have a width Y substantially wider than a width of the first recess 130, whereas the second recess 140 may have a depth X substantially shallower than a depth of the first recess 130. Thus, the second recess 140 may have the width Y larger than the depth X. For example, a ratio between the depth X and the width Y of the second recess 140 may be in a range of about 1.0:1.0 to about 1.0:1.5 when the second recess 140 substantially has an elliptical shape.

In the second etching process for forming the second recess 140 using the etching gas that includes the SF₆ gas, the Cl₂ gas and the O₂ gas, an amount of the O₂ gas may mainly control the depth X of the second recess 140. When the amount of the O₂ gas of the etching gas increases, the second recess 140 may have a more deep depth X so that the cross-section of the second recess 140 may substantially change from an elliptical shape or track shape to a circular shape. For example, when the etching gas includes the SF₆ gas, the Cl₂ gas and the O₂ gas by a flow rate ratio of about 1.0:6.0:0.5, the depth X of the second recess 140 may be augmented so that the second recess 140 may have the circular shape.

In the meantime, the second recess 140 may have an increased width Y when an amount of the SF₆ gas in the etching gas increases. Thus, when the etching gas includes the SF₆ gas by an increased flow rate without augmenting flow rates of the Cl₂ gas and the O₂ gas, the width Y of the second recess 140 may increase so that the second recess 140 may have an elliptical shape or a track shape instead of a circular shape.

Recessed Channel Type Transistor

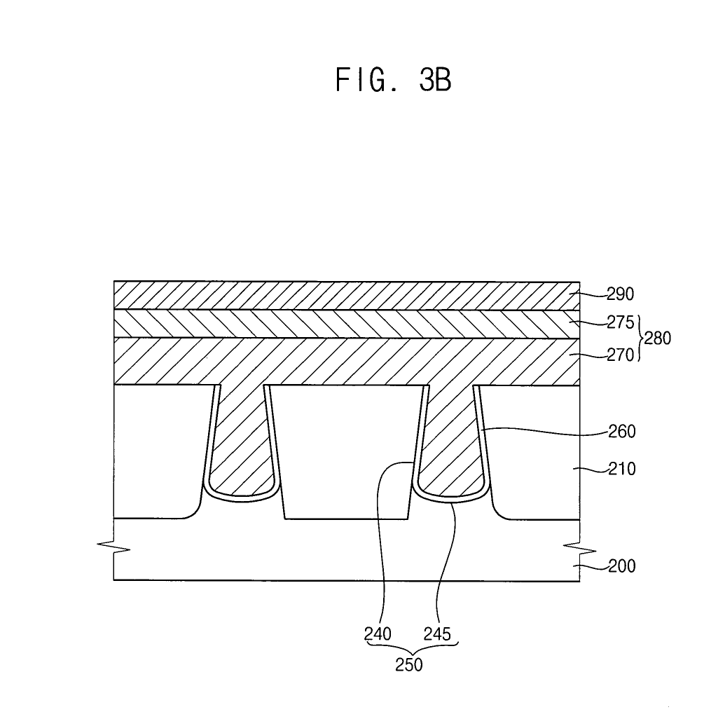

FIGS. 3A and 3B are cross-sectional views illustrating a recessed channel type transistor in accordance with an embodiment of the present invention. FIG. 3A illustrates a cross-section of a recessed channel type transistor along a first direction crossing an active region of a substrate, and FIG. 3B illustrates a cross-section of a recessed channel type transistor along a second direction substantially perpendicular to the first direction.

Referring to FIGS. 3A and 3B, the recessed channel type transistor includes a gate electrode 280 partially buried in a substrate 200, and a gate mask 290 formed on the gate electrode 280.

An isolation layer 210 is formed on the substrate 200 to define an active region of the substrate 200. The isolation layer 210 may include an oxide such as silicon oxide. The recessed channel type transistor is positioned in the active region of the substrate 200.

A recess structure 250 is formed at an upper portion of the substrate 200. As described above, the recess structure 250 includes a first recess 240 (i.e., an upper portion of the recess structure 250) and a second recess 245 (i.e., a lower portion of the recess structure 250). The first recess 240 is formed from an upper face of the substrate 200, and the second recess 245 is positioned beneath the first recess 240. The second recess 245 has a width substantially wider than that of the first recess 240, whereas the first recess 240 has a depth substantially deeper than that of the second recess 245. As shown in FIG. 3B, the first recess 240 has a sidewall inclined by a predetermined angle along the second direction. Thus, the first recess 240 has a lower portion substantially wider than an upper portion thereof. The second recess 245 has a bottom rounded with a predetermined curvature. In particular, the second recess 245 has a rounded sidewall and a rounded bottom between the isolation layers 210 along the second direction. The first recess 240 is generally enlarged from the upper face of the substrate 200. As a result, a silicon fence may not be formed between a sidewall of the recess structure 250 and the isolation layer 210.

The recessed channel type transistor further includes a gate insulation layer pattern 260. The gate insulation layer pattern 260 is formed on a surface of the recess structure 250 and the substrate 200. Namely, the gate insulation layer pattern 260 is positioned on the active region of the substrate 200 and on surfaces of the first and the second recesses 240 and 245. The gate insulation layer pattern 260 may include an oxide such as silicon oxide or a metal oxide having a high dielectric constant.

The gate electrode 280 of the recessed channel type transistor includes a first conductive pattern 270 and a second conductive pattern 275. The gate electrode 280 may have a line shape along the first direction. The first conductive pattern 270 partially fills up the recess structure 250 and extends on the isolation layer 210 along the second direction. Particularly, the recess structure 250 is filled with a lower portion of the first conductive pattern 270, and an upper portion of the first conductive pattern 270 is formed on the lower portion and the isolation layer 210 along the second direction. The first conductive pattern 270 may include polysilicon doped with impurities, a metal or a metal nitride. For example, the first conductive pattern 270 may include titanium (Ti), titanium nitride (TiN), tantalum (Ta), tantalum nitride (TaN), tungsten (W), tungsten nitride (WN), aluminum (Al), aluminum nitride (AlN), copper (Cu), titanium aluminum nitride (TiAlN), etc. These can be used alone or in a mixture thereof.

The second conductive pattern 275 is positioned on the first conductive pattern 270. The second conductive pattern 275 may have a shape substantially identical to the upper portion of the first conductive pattern 270. The second conductive pattern 275 may include a metal silicide, a metal, a metal nitride or polysilicon doped with impurities. For example, the second conductive pattern 275 may include tungsten silicide (WSiₓ), cobalt silicide (CoSiₓ), tantalum silicide (TaSiₓ), titanium silicide (TiSiₓ), titanium, titanium nitride, tantalum, tantalum nitride, tungsten, tungsten nitride, aluminum, aluminum nitride, copper, titanium aluminum nitride, etc. These can be used alone or in a mixture thereof.

According to embodiments of the present invention, the second conductive pattern 275 may include a material substantially identical to that of the first conductive pattern 270. According to embodiments of the present invention, the second conductive pattern 275 may include a material different from that of the first conductive pattern 270.

The gate mask 290 of the recessed channel type transistor is formed on the second conductive pattern 275. The gate mask 290 may have a shape substantially identical to that of the second conductive pattern 275 and/or that of the upper portion of the first conductive pattern 270. The gate mask 290 may include a material that has an etching selectivity relative to the gate electrode 280. For example, the gate mask 290 may include a nitride such as silicon nitride or an oxynitride like silicon oxynitride or titanium oxynitride.

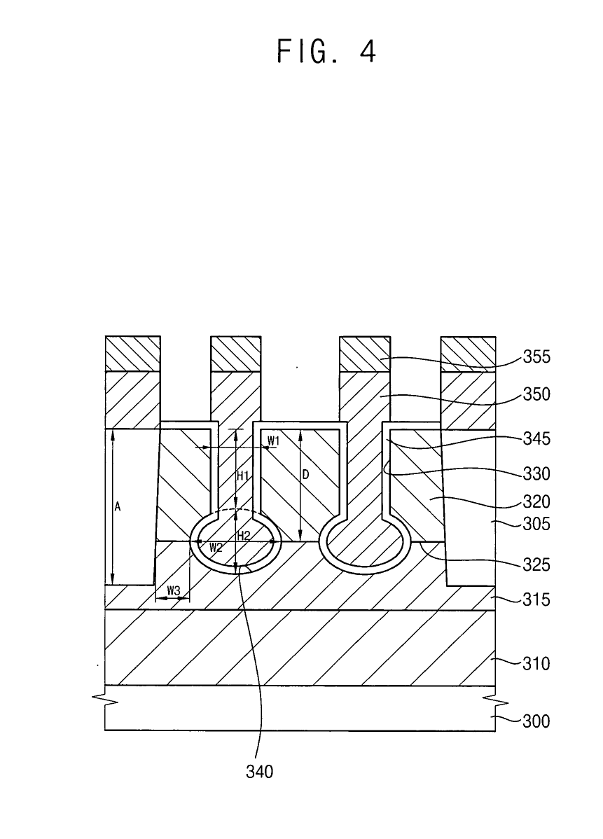

FIG. 4 is a cross-sectional view illustrating a recessed channel type transistor in accordance with an embodiment of the present invention.

Referring to FIG. 4, the recessed channel type transistor includes a gate insulation layer 345, a gate electrode 350, source/drain regions 320 and a gate mask 355.

The gate electrode 350 is partially buried in a recess structure formed in a semiconductor substrate 300. The recess structure has a first recess 330 and a second recess 340. The first recess 330 is vertically formed from an upper face of the substrate 300, and the second recess 340 is positioned beneath the first recess 330.

An isolation layer 305 is formed on a semiconductor substrate 300 to divide the substrate 300 into an active region and a field region. The isolation layer 305 has a first depth A from the upper face of the substrate 300. The source/drain regions 320 have second depth D, substantially smaller than the first depth A of the isolation layer 305.

A first impurity region 310 and a second impurity region 315 are formed in the substrate 300 beneath the source/drain regions 320. The first and the second impurity regions 310 and 315 may have identical conductive types, for example, a P-type. The source/drain regions 320 may have conductive types different from those of the first and the second impurity regions 310 and 315. For example, each of the source/drain regions 320 may have an N-type.

The first recess 330 may be formed in the active region to have a depth H1 of about 1,600 Å to about 2,200 Å, and a width W1 of about 500 Å to about 900 Å. For example, the first recess 330 may have a depth H1 of about 1,900 Å and a width W1 of about 700 Å.

The second recess 340 may have a cross-section with an elliptical shape, a track shape or a circular shape. The second recess 340 may have a maximum width W2 adjacent to a junction 325 formed between the second impurity region 315 and the source/drain regions 320. A ratio between the width and a depth (W2/H2) of the second recess 340 may be in a range of about 1.0:1.0 to about 1.0:1.5. For example, the second recess 340 may have a depth H2 of about 400 to about 600 Å, and a width W2 of about 500 to about 1,350 Å.

The gate insulation layer 345 is formed on surfaces of the first and the second recesses 330 and 340, and on the active region. A lower portion of the gate electrode 350 is buried in the recess structure, and an upper portion of the gate electrode 350 is protruded from the substrate 300.

The junction 325 has a width W3 between the gate electrode 350 and the isolation layer 305. The width W3 of the junction 325 may be adjusted by the width W2 of the second recess 340. When the width W3 of the junction 325 is below about 100 Å, a channel region of the transistor may not be properly formed. On the contrary, when the width W3 of the junction 325 is above about 500 Å, a junction leakage current generated from the junction 325 may increase. Thus, the width W3 of the junction 325 may be in a range of about 100 to about 500 Å. For example, the junction 325 may have a width W3 of about 300 to about 400 Å. Since the width W3 of the junction 325 may be controlled in accordance with the width W2 of the second recess 340, the junction leakage current generated from the junction 325 may be reduced.

Method of Manufacturing a Recessed Channel Type Transistor

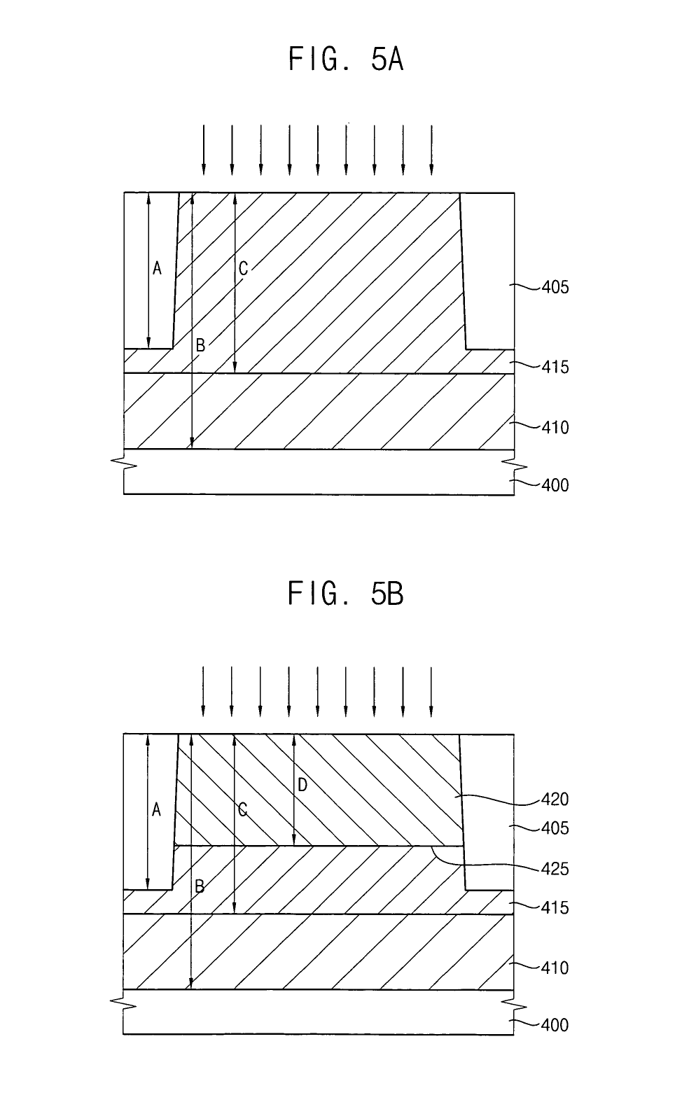

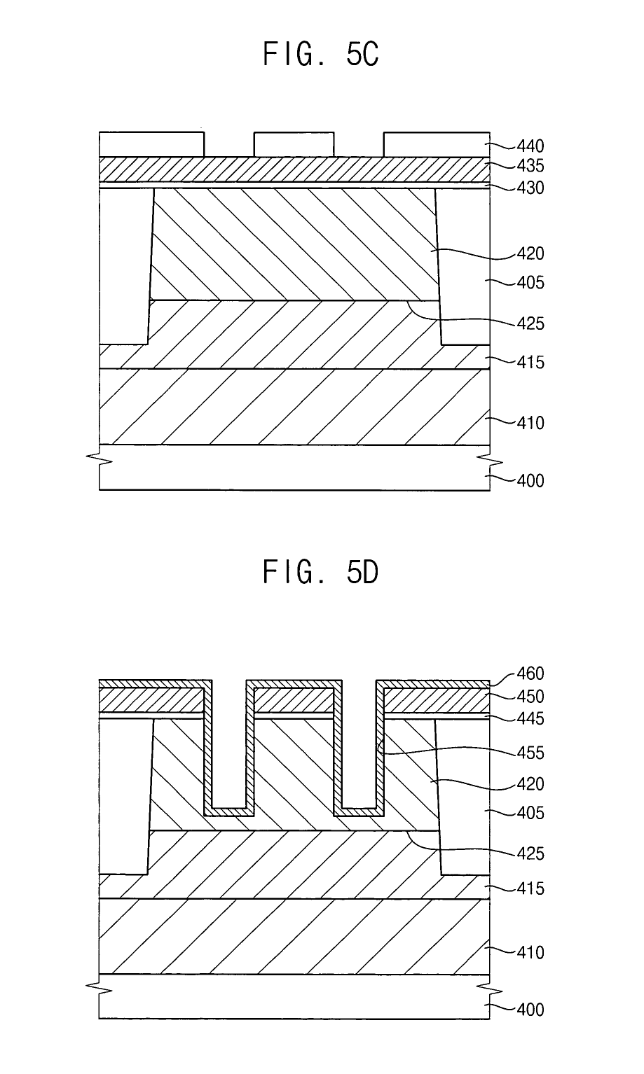

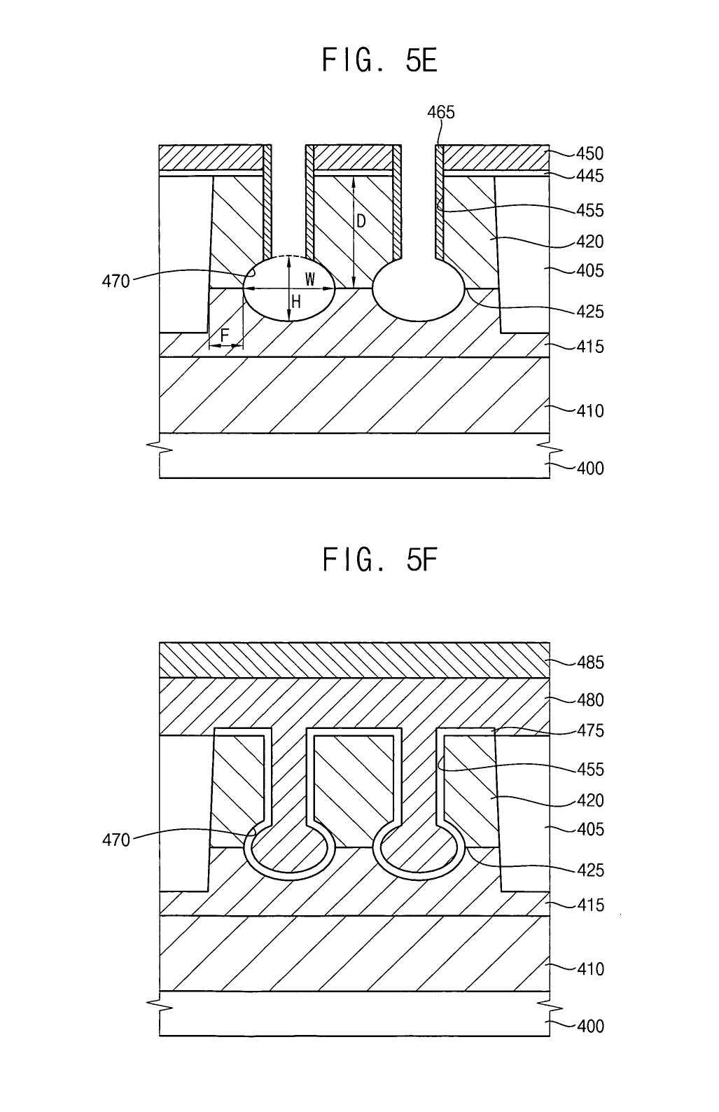

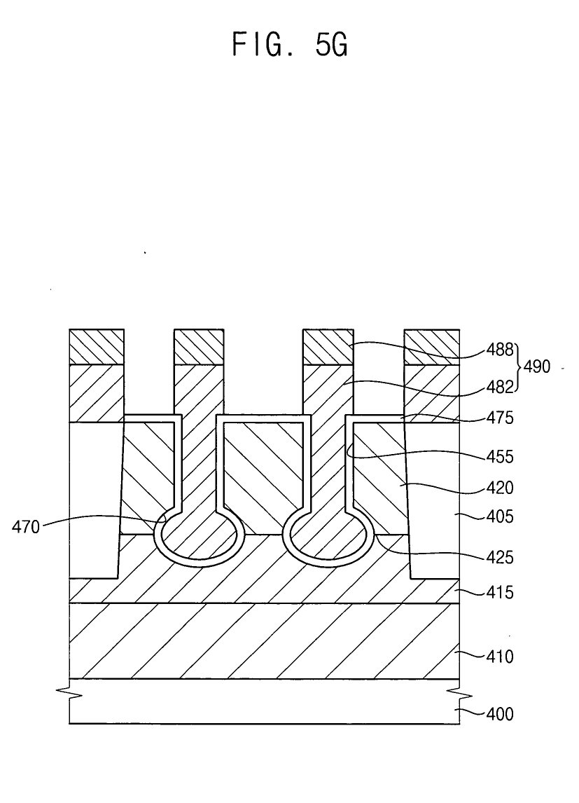

FIGS. 5A to 5G are cross-sectional views illustrating a method of manufacturing a recessed channel type transistor in accordance with embodiments of the present invention.

Referring to FIG. 5A, an isolation layer 405 having a first depth A may be formed on a substrate 400 to define an active region and a field region of the substrate 400. The isolation layer 405 may be formed through an isolation process such as a shallow trench isolation (STI) process. The isolation layer 405 may be formed using an oxide such as silicon oxide. For example, the isolation layer 405 may be formed using phosphor silicate glass (PSG), tetraethylorthosilicate (TEOS), undoped silicate glass (USG), borophosphorous silicate glass (BPSG), HDP-CVD oxide, spin-on glass (SOG), etc. When the isolation layer 405 includes oxide, the isolation layer 405 may be formed by a CVD process, a PECVD process, a HDP-CVD process or a spin coating process. According to embodiments of the present invention, the isolation layer 405 may have a sidewall inclined by an angle of about 80 to 90° relative to an upper face of the substrate 400.

When the isolation layer 405 has a first depth A, each of source/drain regions 420 (see FIG. 5B) has a second depth D, substantially smaller than the first depth A.

A first impurity region 410 is formed in the active region of the substrate 400 by implanting first impurities having a first conductive type and thermally treating the implanted first impurities. The first impurity region 410 has a third depth B, substantially larger than the first depth A of the isolation layer 405. When the first impurity region 410 is formed in the substrate 400, the substrate 400 may be divided into a cell area and a peripheral circuit area.

According to embodiments of the present invention, the first impurity region 410 may be formed using the first impurities having a P-type. For example, the first impurity region 410 may be formed using an element in Group III such as boron (B), gallium (Ga) or indium (In). Additionally, the first impurity region 410 may be formed by implanting the first impurities with an energy of about 90 to about 110 keV to have a first impurity concentration of about 4×10¹¹ to about 4×10¹³ atoms/cm². For example, the first impurity region 410 has a first concentration of about 4×10¹² atoms/cm² by implanting boron (B) with an energy of about 100 keV.

A second impurity region 415 is formed in the first impurity region 410 to have a fourth depth C substantially larger than the first depth A of the isolation layer 405. However, the fourth depth C of the second impurity region 415 is substantially smaller than the third depth B of the first impurity region 410. The second impurity region 415 may control a threshold voltage of the recessed channel type transistor by adjusting an impurity concentration of a channel region of the transistor. The second impurity region 415 may be formed by implanting second impurities having a second conductive type and thermally treating the implanted second impurities. The second impurity region 415 may be formed using elements in Group III such as boron, gallium or indium with an energy of about 40 to about 60 keV to thereby have a second impurity concentration of about 6×10¹¹ and 6×10¹³ atoms/cm². For example, the second impurity region 415 has a second impurity concentration of about 6×10¹² atoms/cm² by implanting boron B with an energy of about 50 keV. In an example embodiment of the present invention, the first impurities of the first impurity region 410 may be substantially identical to the second impurities of the second impurity region 415. In other words, the second conductive type of the second impurities may be a P-type.

Referring to FIG. 5B, the source/drain regions 420 are formed in the second impurity region 415 by implanting third impurities having a third conductive type. Each of the source/drain regions 420 has the second depth D, substantially smaller than the first depth A as described above. The third conductive type of the source/drain regions 420 may be different from the first conductive type of the first impurity region 410 and/or the second conductive type of the second impurity region 415. According to embodiments of the present invention, the source/drain regions 420 may be formed using N-type impurities. For example, the source/drain regions 420 are formed using elements in Group V such as phosphorus (P), arsenic (As) or bismuth (Bi). The source/drain regions 420 may be formed with energies of about 5 to about 15 keV to have third impurity concentrations of about 1×10¹² to about 1×10¹⁴ atoms/cm². For example, the source/drain regions 420 have the third impurity concentrations of about 1×10¹³ atoms/cm² by implanting phosphorus P with energies of about 10 keV.

When the source/drain regions 420 including the third impurities of the N-type are formed in the second impurity region 415 including the second impurities of the P-type, a P-N junction 425 may be generated at an interface between the second impurity region 415 and the source/drain regions 420.

Referring to FIG. 5C, a pad oxide layer 430 and a first hard mask layer 435 are sequentially formed on the substrate 400 having the isolation layer 405. The pad oxide layer 430 and the first hard mask layer 435 may be formed by processes substantially identical to those described with reference to FIG. 2A. Additionally, pad oxide layer 430 and the first hard mask layer 435 may be formed using materials substantially identical to those described with reference to FIG. 2A.

A photoresist pattern 440 is formed on the first hard mask layer 435 to define a portion of the active region where a first recess 455 (see FIG. 5D) is formed.

Referring to FIG. 5D, the first hard mask layer 435 is partially etched using the photoresist pattern 440 as an etch mask to form a first hard mask pattern 450 on the pad oxide layer 430. The first hard mask pattern 450 may be formed by an anisotropic etching process. The photoresist pattern 440 may be removed by an ashing process and/or a stripping process.

The first recess 455 is formed in the source/drain regions 420 of the substrate 400 by partially etching the substrate 400. Simultaneously, a pad oxide layer pattern 445 is formed on the substrate 400. The first recess 455 may be formed by a first etching process using the first hard mask pattern 450 as an etching mask. The first etching process may include an anisotropic etching process. Further, the first etching process may include an RIE process or a CDE process. The first recess 455 may be vertically formed relative to an upper face of the substrate 400.

A protection layer 460 is formed on a sidewall and a bottom of the first recess 455 and on the first hard mask pattern 450. The protection layer 460 may have a thickness of about 40 to about 100 Å when the first recess 455 has a width of about 500 to about 900 Å. The first recess 455, the pad oxide layer pattern 445 and the protection layer 460 may be formed through processes substantially identical to those described with reference to FIG. 2B.

Referring to FIG. 5E, the protection layer 450 is partially etched to form a protection layer pattern 465 on the sidewall of the first recess 455. The protection layer pattern 450 may be formed by an etch back process. When the protection layer pattern 450 is formed on the sidewall of the first recess 455, a portion of the substrate 400 is exposed through the bottom of the first recess 455.

The exposed portion of the substrate 400 through the first recess 455 is etched to form a second recess 470 beneath the first recess 455. Thus, a recess structure having the first and the second recesses 455 and 470 is formed in the active region of the substrate 400. The second recess 470 may be formed by a second etching process. The second etching process may include an isotropic dry etching process using an etching gas that contains an SF₆ gas, a Cl₂ gas and an O₂ gas. The second recess 470 has a width substantially wider than that of the first recess 455. For example, the second recess 470 has a width of about 500 to about 1,350 Å. The second recess 470 has an elliptical shape or a track shape. Since the second recess 470 has an enlarged width, a channel region of the transistor enclosing the second recess 470 may have a greatly increased length. When the second recess 470 has an elliptical shape, a ratio between the width and the depth (W/H) of the second recess 470 may be in a range of about 1.0:1.0 to about 1.0:1.5.

The second recess 470 may have a maximum width W adjacent to the second depth D of the P-N junction 425. Accordingly, the P-N junction 425 between the second recess 470 and the isolation layer 405 may have a reduced width. As a result, a junction leakage current from the P-N junction 425 may decrease.

Referring to FIG. 5F, the first hard mask pattern 450, the pad oxide layer pattern 445 and the protection layer pattern 465 are removed. The first hard mask pattern 450, the pad oxide layer pattern 445 and the protection layer pattern 465 may be etched by a wet etching process using an etching solution including H₂PO₄ and/or a diluted HF solution. When the pad oxide layer pattern 445 and the protection layer pattern 465 are removed, a portion of the substrate 400 around the first recess 455 is exposed and portions of the substrate 400 are simultaneously exposed through the sidewalls and bottoms of the first and the second recesses 455 and 470.

A gate insulation layer 475 is formed on the exposed portions of the substrate 400. Particularly, the gate insulation layer 475 is formed on the active region and the sidewalls and the bottoms of the first and the second recesses 455 and 470. The gate insulation layer 475 may be formed by a thermal oxidation process, a CVD process or an ALD process. The gate insulation layer 475 may be formed using an oxide or a metal oxide having a high dielectric constant. When the gate insulation layer 475 is formed using the oxide, the gate insulation layer 475 may have a thickness of about 40 to about 100 Å. According to embodiments of the present invention, the gate insulation layer 475 may be formed using the metal oxide such as titanium oxide (TiO₂), hafnium oxide (HfO₂), aluminum oxide (Al₂O₃), zirconium oxide (ZrO₂), etc.

A first conductive layer 480 is formed on the gate insulation layer 475 to fill up the first and the second recesses 455 and 470. The first conductive layer 480 may be formed using doped polysilicon, a metal or a metal nitride by a CVD process, a low-pressure chemical vapor deposition (LPCVD) process, a PECVD process, an ALD process, a pulsed laser deposition (PLD) process or a sputtering process. In a process for forming the first conductive layer 480 of doped polysilicon, impurities may be doped into a polysilicon layer by a diffusion process, an ion implantation process or an in-situ doping process after the polysilicon layer is formed on the gate insulation layer 475.

A second conductive layer 485 is formed on the first conductive layer 480. The second conductive layer 485 may be formed using a metal silicide, a metal, a metal nitride or doped polysilicon. The second conductive layer 485 may have a multi-layer structure that includes a metal silicide layer and a metal layer. For example, the second conductive layer 485 is formed using tungsten silicide, titanium silicide, cobalt silicide, tantalum silicide, titanium, tantalum, tungsten, aluminum and/or copper.

Referring to FIG. 5G, after a second hard mask pattern (not shown) is formed on the second conductive layer 485, the second and the first conductive layers 485 and 480 are partially etched using the second hard mask as an etching mask, thereby forming the gate electrode 490 in the active region. The second and the first conductive layers 485 and 480 may be etched by an anisotropic etching process. The gate electrode 490 includes a first conductive pattern 482 and a second conductive pattern 488. The gate electrode 490 may be formed by an RIE process or a CDE process. Since the first conductive pattern 482 fills up the first and the second recesses 455 and 470, the gate electrode 490 is adjacent to the source/drain regions 420. When the gate electrode 490 is formed in the active region of the substrate 400, the recessed channel type transistor is formed on the substrate 400.

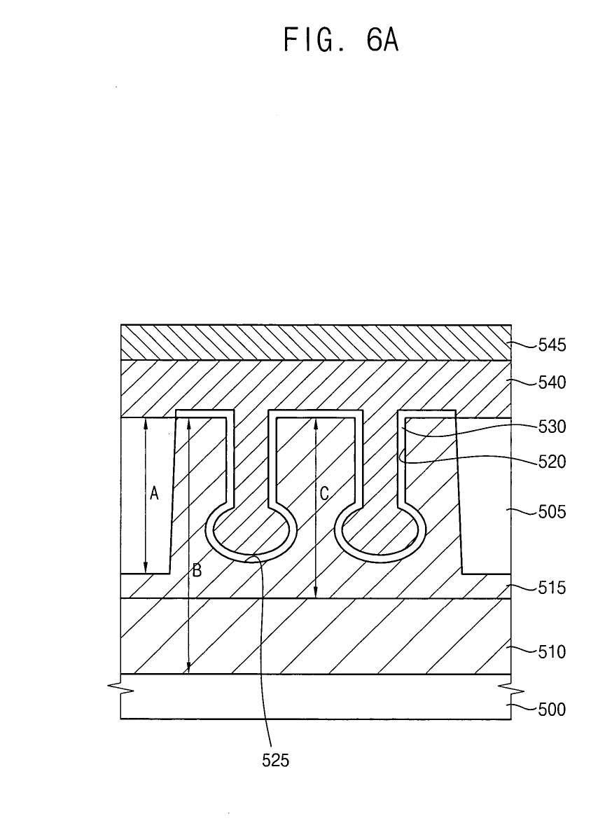

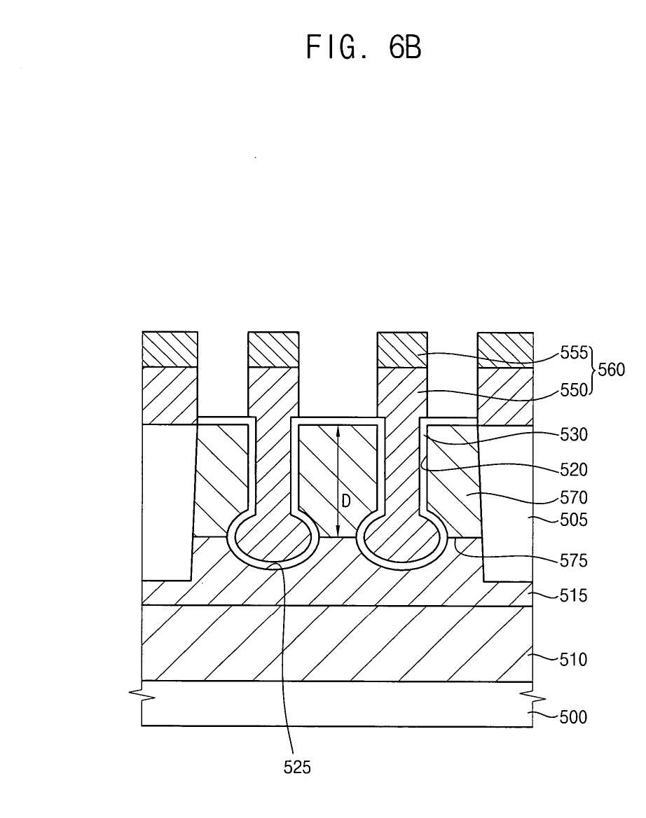

FIGS. 6A and 6B are cross-sectional views illustrating a method of manufacturing a recessed channel type transistor in accordance with an embodiment of the present invention.

Referring to FIG. 6A, an isolation layer 505 is formed on a semiconductor substrate 500 to define an active region and a field region. The isolation layer 505 may have a first depth A from an upper face of the substrate 500. When the isolation layer 505 has a first depth A, each of source/drain regions 570 (see FIG. 6B) has a second depth D, substantially smaller than the first depth A of the isolation layer 505.

A first impurity region 510 is formed in the active region of the substrate 500 by implanting first impurities having a first conductive type. The first impurity region 510 may have a third depth B substantially larger than the first depth A. The substrate 500 may be divided into a cell area and a peripheral circuit area in accordance with the formation of the first impurity region 510.

A second impurity region 515 is formed in the first impurity region 510 by implanting second impurities having a second conductive type substantially identical to that of the first impurities. The second impurity region 515 may have a fourth depth C substantially larger than the second depth D of the source/drain regions 570, whereas the fourth depth C is substantially smaller than the third depth B of the first impurity region 510. The second impurity region 515 may adjust a threshold voltage of the transistor by controlling an impurity concentration of a channel region of the transistor. The isolation layer 505, the first impurity region 510 and the second impurity region 515 may be formed by processes substantially identical to those described with reference to FIG. 5A.

After a first hard mask pattern (not shown) is formed on the substrate 500 including the isolation layer 505, a first recess 520 is formed in the active region of the substrate 500 by a first etching process.

A protection layer pattern (not shown) is formed on a sidewall of the first recess 520. When the protection layer is formed, a portion of the substrate 500 is exposed through a bottom of the first recess 520.

A second recess 525 is formed beneath the first recess 520 by etching the exposed portion of the substrate 500. For example, the second recess 525 may be formed by a second etching process using an etching gas that contains an SF₆ gas, a Cl₂ and an O₂ gas. The second recess 525 has a width substantially wider than that of the first recess 520.

After removing the first hard mask pattern and the protection layer pattern, a gate insulation layer 530 is continuously formed on the sidewalls and the bottoms of the first and the second recesses 520 and 525.

A first conductive layer 540 is formed on the gate insulation layer 530 to fill up the first and the second recesses 520 and 525, and then a second conductive layer 545 is formed on the first conductive layer 540.

Referring to FIG. 6B, after a second hard mask pattern (not shown) is formed on the second conductive layer 545, the second and the first conductive layers 545 and 540 are sequentially etched using the second hard mask pattern as an etching mask to thereby form a gate electrode 560 in the active region. The gate electrode 560 includes a first conductive pattern 550 and a second conductive pattern 555.

The source/drain regions 570 are formed portions of the active region adjacent to the gate electrode 560, and are formed by implanting impurities into the substrate 500. Each of the source/drain regions 570 has the second depth D. The source/drain regions 570 are formed from surface portions of the substrate 500 to portions of the substrate 500 where the gate electrode 560 substantially has a maximum width. When the source/drain regions 570 are formed in the active region, junctions 575 are generated at interfaces between the source/drain regions 570 and the second impurity regions 515. As a result, the recessed channel type transistor including the gate insulation layer 530, the gate electrode 560 and the source/drain region 570 are formed on the substrate 500.

As described above, the junction 575 may have a greatly reduced width since the gate electrode 560 has a lower portion enlarged along a vertical direction and a horizontal direction. Hence, a junction leakage current generated through the junction 575 may be much reduced. In addition, when the lower portion of the gate electrode 560 may be enlarged as an elliptical shape or a track shape, the recessed channel type transistor may have a much increased channel length because the channel region of the transistor is formed along the enlarged lower portion of the gate electrode 560.

According to embodiments of the present invention, a recessed channel type transistor includes a gate electrode that has a lower portion partially buried in a substrate and enlarged as an elliptical shape, a track shape or a circular shape in accordance with a recess structure. Additionally, the recessed channel type transistor includes source/drain regions formed from an upper face of the substrate to a portion of the substrate where the gate electrode has a maximum width. Thus, a junction of the transistor may have a reduced width to thereby decrease a junction leakage current from the junction. Further, the transistor may include a channel region having a greatly increased length in accordance with the enlarged gate electrode because the channel region is formed along the gate electrode. As a result, the recessed channel type transistor may have enhanced electrical characteristics and an improved reliability.

The foregoing is illustrative of the present invention and is not to be construed as limiting thereof. Although a few example embodiments of the present invention have been described, those skilled in the art will readily appreciate that many modifications are possible in the example embodiments without materially departing from the novel teachings and advantages of the present invention. Accordingly, all such modifications are intended to be included within the scope of the present invention as defined in the claims. In the claims, means-plus-function clauses are intended to cover the structures described herein as performing the recited function and not only structural equivalents but also equivalent structures. Therefore, it is to be understood that the foregoing is illustrative of the present invention and is not to be construed as limited to the specific embodiments disclosed, and that modifications to the disclosed embodiments, as well as other embodiments, are intended to be included within the scope of the appended claims. The present invention is defined by the following claims, with equivalents of the claims to be included therein.

What is claimed is:

1. A recessed channel type transistor comprising:
a gate insulation layer formed on a surface of a recess structure formed in a substrate, the recess structure including a first recess formed from an upper face of the substrate and a second recess formed beneath the first recess, wherein the second recess has a width larger than a width of the first recess; and
a gate electrode formed on the gate insulation layer and partially buried in the recess structure.

2. The transistor of claim 1, wherein the first recess has an inclined sidewall, and the second recess has a rounded sidewall and a rounded bottom.

3. The transistor of claim 1, wherein the gate electrode comprises a lower portion partially buried in the recess structure, and an upper portion that protrudes from the upper face of the substrate.

4. The transistor of claim 1, wherein the gate electrode comprises a first conductive pattern partially buried in the recess structure, and a second conductive pattern formed on the first conductive pattern.

5. A method of forming a recess structure comprising:
forming a first recess in a substrate by a first etching process;
forming a protection layer pattern on a sidewall of the first recess; and
forming a second recess beneath the first recess by a second etching process using an etching gas containing an SF₆ gas, a Cl₂ gas and an O₂ gas, the second recess having a width larger than a width of the first recess.

6. The method of claim 5, wherein the first etching process comprises an isotropic etching process, and the second etching process comprises an anisotropic etching process.

7. The method of claim 5, wherein a flow rate ratio among the SF₆ gas, the Cl₂ gas and the O₂ gas is in a range of about 1.0:6.0:0.2 to about 1.0:6.0:0.3.

8. The method of claim 5, wherein the second etching process is performed at a pressure of about 15 to about 25 mTorr and for about 5 to about 15 seconds by applying a power of about 400 to about 600 W.

9. The method of claim 5, wherein the second recess substantially has a cross-section with an elliptical shape, a track shape or a circular shape.

10. The method of claim 5, wherein a ratio between the width of the second recess and a depth of the second recess is in a range of about 1.0:1.0 to about 1.0:1.5.

11. The method of claim 5, wherein the protection layer pattern is formed using a material that has an etching selectivity to the substrate.

12. The method of claim 11, wherein the protection layer pattern is formed using silicon oxide, silicon nitride or titanium nitride.

13. A method of manufacturing a recessed channel type transistor comprising:
forming an isolation layer having a first depth from an upper face of a substrate;
forming source/drain regions including junctions in an active region of the substrate, each of the source/drain regions having a second depth substantially smaller than the first depth;
forming a first recess in the source/drain regions by a first etching process;
forming a protection layer pattern on a sidewall of the first recess;
forming a second recess beneath the first recess by a second etching process using an etching gas containing an SF₆ gas, a Cl₂ gas and an O₂ gas, the second recess having a width substantially larger than a width of the first recess;
forming a gate insulation layer on surfaces of the first and the second recesses; and
forming a gate electrode on the gate insulation layer to fill up the first recess and the second recess.

14. The method of claim 13, wherein the isolation layer is inclined by an angle of about 80 to about 90° relative to a surface of the substrate.

15. The method of claim 13, wherein the second recess has a maximum width adjacent to the junction.

16. The method of claim 13, prior to forming the source/drain regions, further comprising:
forming a first impurity region in the substrate, the first impurity region having a third depth substantially greater than the first depth; and
forming a second impurity region in the first impurity region, the second impurity region having a fourth depth substantially greater than the second depth and substantially smaller than the third depth, wherein the source/drain regions are formed in the second impurity region.

17. The method of claim 16, wherein the first and the second impurity regions each have a first conductive type, and the source/drain regions each have a second conductive type, different from the first conductive type.

18. The method of claim 17, wherein the first impurity region is formed by implanting elements in Group III with an energy of about 90 to about 110 keV to have a first impurity concentration of about 4×10¹¹ to about 4×10¹³ atoms/cm², the second impurity region is formed by implanting elements in Group III with an energy of about 40 to about 60 keV to have a second impurity concentration of about 6×10¹¹ to about 6×10¹³ atoms/cm², and the source/drain regions are formed by implanting elements in Group V with energies of about 5 to about 15 keV to have third impurity concentrations of about 1×10¹² to about 1×10¹⁴ atoms/cm².

19. The method of claim 13, prior to forming the gate insulation layer, further comprising removing the protection layer pattern.

20. The method of claim 13, wherein the first recess has a width of about 500 to about 900 Å.

21. The method of claim 13, wherein the protection layer pattern has a thickness of about 40 to about 100 Å.

22. The method of claim 13, wherein the second recess has a width of about 500 to about 1,350 Å.

23. A method of manufacturing a recessed channel type transistor comprising:
forming an isolation layer having a first depth from an upper face of a substrate;
forming a first recess in the substrate by a first etching process;
forming a protection layer pattern on a sidewall of the first recess;
forming a second recess beneath the first recess by a second etching process using an etching gas containing an SF₆ gas, a Cl₂ gas and an O₂ gas, the second recess having a width substantially larger than a width of the first recess;
forming a gate insulation layer on surfaces of the first and the second recesses;
forming a gate electrode on the gate insulation layer; and
forming source/drain regions having junctions adjacent to the gate electrode, wherein each of the junctions has a second depth substantially smaller than the first depth.

24. A recessed channel type transistor comprising:
an isolation layer having a first depth from an upper face of a substrate;
source/drain regions formed in the substrate, the source/drain regions including junctions having second depths substantially smaller than the first depth;
a gate insulation layer formed on a surface of a recess structure formed in the substrate adjacent to the source/drain regions, the recess structure including a first recess formed between the source/drain regions and a second recess formed beneath the first recess, wherein the second recess has a maximum width adjacent to the second depth; and
a gate electrode formed on the gate insulation layer to fill up the recess structure.

25. The transistor of claim 24, wherein the junctions are positioned between the isolation layer and the second recess.

26. The transistor claim 24, wherein the gate electrode comprises a lower portion having an enlarged cross-section with an elliptical shape, a track shape or a circular shape.
